(19) United States
(12) Patent Application Publication
(10) Pub. No.: US 2011/0295599 A1
(43) Pub. Date: Dec. 1, 2011

(54) Aligning Scheme for Audio Signals

(75) Inventors: Volodya Grancharov, Solna (SE); Anders Ekman, Stockholm (SE)

(73) Assignee: TELEFONAKTIEBOLAGET LM ERICSSON (PUBL), Stockholm (SE)

(21) Appl. No.: 13/146,107

(22) PCT Filed: Jan. 26, 2009
(86) PCT No.: PCT/SE2009/050077

§ 371 Date: Aug. 15, 2011

(51) Int. Cl. G10L 19/14; H03L 7/00

(52) U.S. Cl. 704/211; 327/162; 704/E19.001

(57) ABSTRACT

Methods, devices, and computer programs described herein may segment a reference signal that corresponds to a non-degraded signal into a plurality of reference signal segments; generate filter coefficients based on each reference signal segment; and filter each reference signal segment with its corresponding generated filter coefficients. The methods, devices, and computer programs may also filter a degraded signal, which includes a delayed signal of the reference signal, with each of the generated filtering coefficients to produce a number of degraded signals equivalent to a number of the plurality of reference signal segments; perform time-wise alignment for each filtered degraded signal with respect to each corresponding filtered reference signal segment; and output a time offset based on the performing.

### TECHNICAL FIELD

Implementations described herein relate generally to signal processing. More particularly, implementations described herein relate to schemes for time-aligning signals.

### BACKGROUND

Delay estimation is difficult to perform when one of the signals is distorted. The distortion may originate from various sources, such as, for example, coding, filtering, gain, additive background noise, etc. Additionally, a signal may include various types of delay, such as, for example, a constant delay, a piecewise constant delay, a continuous variation of delay, etc., which further complicates the problem, due to the local mismatch between local distortion and local misalignment.

Some conventional approaches utilize time domain methods (e.g., cross-correlation) to align signals. However, such approaches do not preserve, particularly in the case of low bit rate codecs, a waveform of an input signal and an output signal of a system. In other approaches, time domain methods may be coupled with subsequent frequency domain methods. However, while such approaches may appear more reliable, they are not, since frequency domain information is used locally, as a subsequent step, after time domain crude alignment is performed. Thus, when the time domain alignment is not accurate, a frequency domain alignment is unable to compensate for the inaccuracies stemming from the time domain alignment.

### SUMMARY

It is an object to object to obviate at least some of the above disadvantages and to improve in the aligning of signals in the time and frequency domains. In the embodiments described, a signal alignment scheme performs time alignment and frequency alignment in a combined manner by filtering a degraded signal in correspondence to a spectral content of a reference signal and time-aligning the filtered reference signal and degraded signal. This is contrast to simply performing time alignment or, alternatively, performing a time alignment and then a frequency alignment.

According to one aspect, a method may be performed by a device for aligning signals having a time delay difference. The method may include segmenting a reference signal that corresponds to a non-degraded signal into a plurality of reference signal segments; generating filter coefficients based on each reference signal segment; filtering each reference signal segment with its corresponding generated filter coefficients; filtering a degraded signal, which includes a delayed signal of the reference signal, with each of the generated filtering coefficients to produce a number of degraded signals equivalent to a number of the plurality of reference signal segments; performing time-wise alignment for each filtered degraded signal with respect to each corresponding filtered reference signal segment; and outputting a time offset based on the performing.

According to another aspect, a device for aligning signals having a time delay difference may include a signal alignment system to segment a reference signal, which corresponds to a non-degraded signal, into a plurality of reference signal segments; generate filter coefficients based on each reference signal segment; filter each reference signal segment with its corresponding generated filter coefficients; filter a degraded signal, which includes the reference signal that is delayed, with each of the generated filtering coefficients to produce a number of degraded signals equivalent to a number of the plurality of reference signal segments; perform time-wise alignment for each filtered degraded signal with respect to each corresponding filtered reference signal segment; and output a time offset corresponding to the time delay difference.

According to yet another aspect, a computer-readable medium may include instructions to segment a reference signal that corresponds to a non-degraded signal into a plurality of reference signal segments; generate filter coefficients based on each reference signal segment; filter each reference signal segment with its corresponding generated filter coefficients; filter a degraded signal, which includes the reference signal that is delayed, with each of the generated filtering coefficients to produce a number of degraded signals equivalent to a number of the plurality of reference signal segments; perform time-wise alignment for each filtered degraded signal with respect to each corresponding filtered reference signal segment; and output a time offset based on the performing.

### BRIEF DESCRIPTION OF THE DRAWINGS

FIG. 1 is a diagram illustrating an exemplary signal aligning system (SAS);

FIG. 2 is a diagram illustrating an exemplary device that may include the SAS depicted in FIG. 1;

FIG. 3 is a flow diagram illustrating an exemplary process for aligning signals;

FIG. 4 is a diagram illustrating an exemplary reference signal and an exemplary degraded signal;

FIG. 5 is a diagram illustrating exemplary frequency responses for filtering segments associated with the reference signal and the degraded signal; and

FIG. 6 is a diagram illustrating root mean square error (RMSE) signals associated with the reference signal and the degraded signal.

### DETAILED DESCRIPTION

The following detailed description refers to the accompanying drawings. The same reference numbers in different drawings may identify the same or similar elements. Also, the following description does not limit the invention. Rather, the scope of the invention is defined by the appended claims.

Embodiments described herein provide a signal alignment scheme for aligning signals and determining a time offset between signals. The signal alignment scheme may be implemented in a device (e.g., a computer) or some other type of signal processing and/or signal quality measuring device (e.g., an voice/audio quality analyzing device). The signal alignment scheme may determine a time offset between input and output signals associated with a variety of systems, such as, for example, a communication network (e.g., a telephone network or some other type of voice network), a device (e.g., a telephone, or some other type of audio device), or other types of systems or audio equipment. As will be described, unlike existing techniques for aligning signals, the signal alignment scheme performs time alignment and frequency alignment in a combined manner.

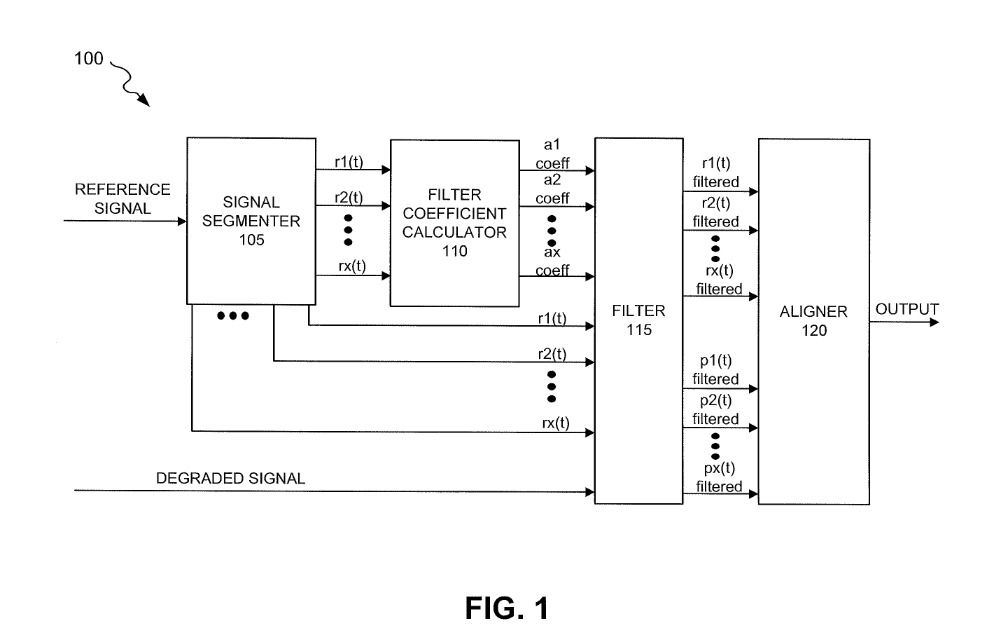

FIG. 1 is a diagram illustrating exemplary functional components of a signal alignment system (SAS) 100. Each of these functional components may be implemented in hardware, hardware and software, firmware, etc. As illustrated, SAS 100 may include a signal segmenter 105, a filter coefficient calculator 110, a filter 115, and an aligner 120. A reference signal and a degraded signal may be input to SAS 100 for alignment. The reference signal may correspond to a digital signal that is clean (i.e., a non-degraded signal). That is, a non-degraded digital signal may not include any form of delay, distortion, or other form of signal degradation (e.g., noise). On the other hand, the degraded signal may correspond to a digital signal that does include one or more forms of delay (e.g., a time-warped signal), and perhaps distortion and/or other forms of signal degradation (e.g., noise). The term “delay,” is intended to be broadly interpreted to include a signal having one or multiple forms of delay. For example, the delay may include a constant delay, a piecewise constant delay, and/or a continuous variation of delay. The degraded signal may correspond to a digital signal that traversed a number of nodes in a communication network causing degradation of the signal.

In an exemplary process, signal segmenter 105 may receive a signal (e.g., the reference signal) as input and output multiple segments (e.g., two or more segments) of the reference signal. For example, signal segmenter 105 may output multiple reference signal segments, such as, (r1(t)) through (rx(t)). Filter coefficient calculator 110 may receive each of reference signal segments (r1(t)) through (rx(t)) and output corresponding filtering coefficients. For example, filter coefficient calculator 110 may output filtering coefficients (a1) through (ax) that correspond to a spectral content of reference signal segments (r1(t)) through (rx(t)). Each of the filtering coefficients (a1) through (ax) may correspond to a vector of coefficient values. The filtering coefficients (a1) through (ax) may be calculated based on various techniques, such as, for example, autoregressive (AR) modeling (e.g., Yule-Walker, Burg, Levinson, Levinson-Durbin, Schur-Cohn, etc.) using linear prediction.

Filter 115 may filter signals according to the filter coefficients (a1) through (ax). For example, as illustrated in FIG. 1, reference signal segments (r1(t)) through (rx(t)) may be input to filter 115. Filter 115 may output filtered reference signal segments (r1(t)) through (rx(t)). Additionally, a degraded signal may be input to filter 115. The degraded signal may be filtered by each of the filtering coefficients (a1) through (ax). In accordance thereto, filter 115 may output filtered degraded signal segments (p1(t)) through (px(t)).

Aligner 120 may receive both the filtered reference signal segments (r1(t)) through (rx(t)) and the filtered degraded signal segments (p1(t)) through (px(t)). Aligner 120 may perform time-wise alignment for each filtered reference signal segment (r1(t)) through (rx(t)) with respect to each corresponding filtered degraded signal segment (p1(t)) through (px(t)). In one implementation, aligner 120 may determine a maximum correlation between each filtered reference segment and corresponding filtered degraded signal pair. Aligner 120 may align the reference signal and the degraded signal based on the determined maximum correlation associated with the filtered reference signal segment and the filtered degraded signal segment pair. In another implementation, aligner 120 may determine an error signal for each filtered reference signal segment and corresponding filtered degraded signal pair. Aligner 120 may select a minimum error signal from the determined error signals. Aligner 120 may align the reference signal and the degraded signal based on the selected minimum error signal associated with the filtered reference signal segment and the filtered degraded signal segment pair.

Although FIG. 1 illustrates exemplary functional components of SAS 100, in other implementations, SAS 100 may include additional, fewer, or different functional components than those described. Additionally, or alternatively, in other implementations, the number and/or the arrangement of functional components may be different. Additionally, or alternatively, in other implementations, one or more of the functional components of SAS 100 may be capable of performing one or more other operations as described as being performed by other functional component(s) of SAS 100.

As previously mentioned, the signal alignment scheme may determine a time offset between input and output signals associated with a variety of systems, such as, for example, a communication network. The term “communication network,” is intended to be broadly interpreted to include a wireless network, such as a cellular network, a mobile network, a non-cellular network, a satellite network, or a wired network. For example, the communication network may correspond to a communication network for voice (e.g., a telephone network, a Voice Over Internet Protocol (VOIP) network, etc.) or a communication network for some other type of audio signals (e.g., music, MP3, digital video broadcasting (DAB), digital audio broadcasting (DAB), etc.). By way of example, SAS 100 may receive a reference signal (e.g., a voice signal) from an end point (e.g., a user terminal) and a degraded signal, which propagated through the communication network, from another end point (e.g., a caller/callee scenario). It will be appreciated, however, that other nodes (e.g., a gateway, an access point, etc.) of the communication network may provide the reference signal and/or the degraded signal. Additionally, the signal alignment scheme may have application with respect to testing various devices (e.g., telephones, cell phones, mobile phones, etc.), or other types of audio equipment or systems.

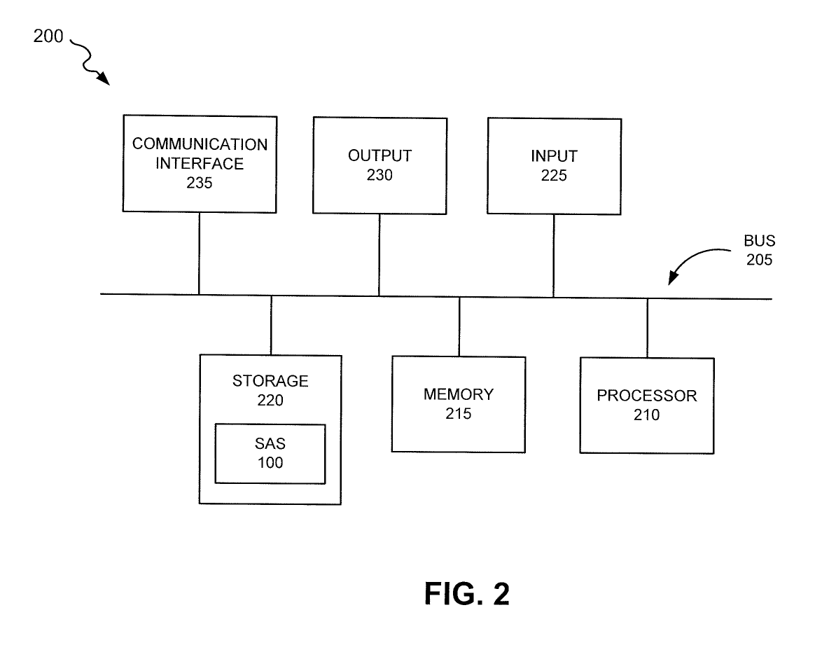

FIG. 2 is a diagram illustrating exemplary components of a device 200 that may implement SAS 100. For example, device 200 may correspond to a computer or some other type of signal processing device. As illustrated, device 200 may include a bus 205, a processing system 210, memory 215, storage 220, an input 225, an output 230, and a communication interface 235.

Bus 205 may include a path that permits communication among the components of device 200. For example, bus 205 may include a system bus, an address bus, a data bus, and/or a control bus. Bus 205 may also include bus drivers, bus arbiters, bus interfaces, and/or clocks.

Processor 305 may interpret and/or execute instructions. For example, processor 205 may include a general-purpose processor, a microprocessor, a data processor, a co-processor, a network processor, an application specific integrated circuit (ASIC), a controller, a programmable logic device, a chipset, a field programmable gate array (FPGA), and/or some other processing logic that may interpret and/or execute instructions and/or data.

Memory 215 may store information (e.g., data, instructions, etc.). Memory 215 may include volatile memory and/or non-volatile memory. For example, memory 215 may include random access memory (RAM), dynamic random access memory (DRAM), static random access memory (SRAM), read only memory (ROM), programmable read only memory (PROM), erasable programmable read only memory (EPROM), flash memory, and/or some other form of storing hardware.

Storage 220 may store information (e.g., data, an application, etc.). For example, storage 220 may include a hard disk (e.g., a magnetic disk, an optical disk, a magneto-optic disk, etc.) and/or some other type of storing medium. In one implementation, SAS 100 may correspond to one or multiple applications stored in storage 220. However, as previously mentioned, each of the functional components (e.g., signal segmenter 105, filter coefficient calculator 110, filter 115, and aligner 120) of SAS 100 may be implemented in hardware (e.g., processor 205), firmware, or hardware and software. Additionally, SAS 100 may implemented in a centralized manner (e.g., on a single device) or in a distributed manner (e.g., on multiple devices).

Input 225 may permit information to be input into device 200. For example, input 225 may include a keyboard, a keypad, a touch screen, a touch pad, a mouse, a port, a button, a switch, a microphone, voice recognition logic, and/or some other type of input component. Output 230 may permit information to be output from device 200. For example, output 230 may include a display, a speaker, light emitting diodes (LEDs), a port, or some other type of output component.

Communication interface 235 may enable device to communicate with other devices, systems, networks, etc. For example, communication interface 235 may include an Ethernet interface, an optical interface, a coaxial interface, a wireless interface or the like.

Although FIG. 2 illustrates exemplary components of device 200, in other implementations, device 200 may include fewer, additional, and/or different components than those depicted in FIG. 2. Additionally, it will be appreciated that the arrangement of components depicted in FIG. 2 may be different in other implementations.

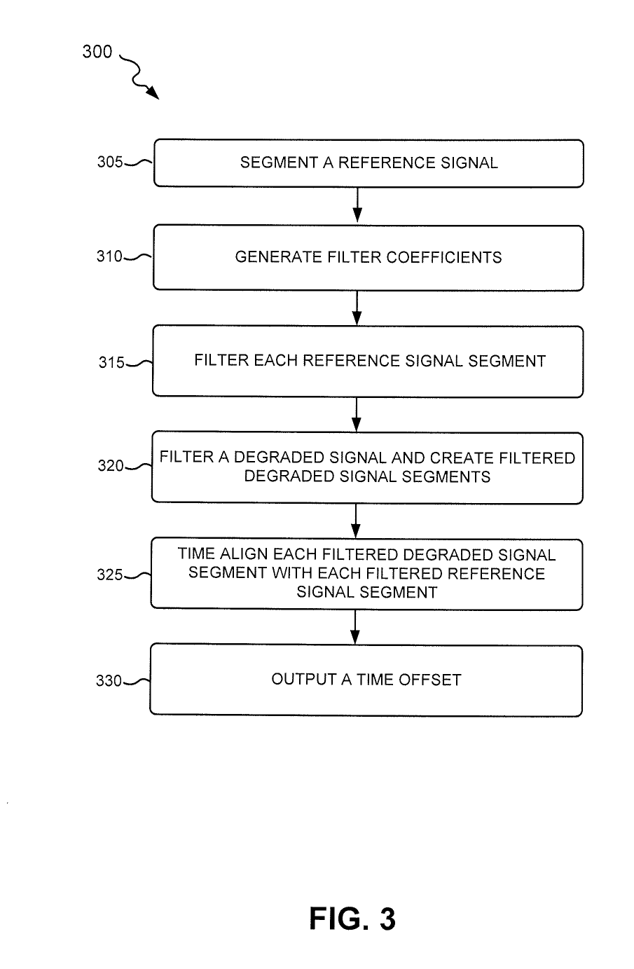

FIG. 3 is a flow diagram illustrating an exemplary process 300 for aligning signals and determining a time offset. The exemplary process 300 may be performed by SAS 100. By way of example, SAS 100 may be implemented by one or more components of device 200 (e.g., a computer).

Process 300 may begin with segmenting a reference signal (block 305). A reference signal may be input to signal segmenter 105. Signal segmenter 105 may segment the reference signal into two or more segments. Each segment of the reference signal may correspond to a time period (e.g., a time window or a time index) of the reference signal.

Filter coefficients may be generated (block 310). Filter coefficient calculator 110 may generate filter coefficients that correspond to a spectral content (e.g., a spectrum envelope) for each reference signal segment. In one implementation, filter coefficient calculator 110 may utilize parametric methods to create a filter having a frequency response that follows the spectral content of each reference signal segment. For example, filter coefficient calculator 110 may generate an AR model using linear prediction. For example, various algorithms, such as, Yule-Walker, Burg, Levinson, Levinson-Durbin, Schur-Cohn, etc., may be utilized. In another implementation, filter coefficient calculator 110 may generate an AR moving average model. Alternatively, filter coefficient calculator 110 may utilize a non-parametric method to create a filter having a frequency response that follows the spectral content of each reference signal segment. For example, filter coefficient calculator 110 may generate a discrete power spectrum estimation (e.g., a periodogram). In the implementations described, filter 115 may utilize the generated filter coefficients to filter the reference signal segments and the degraded signal, as described below.

Each reference signal segment may be filtered (block 315). Each reference signal segment may be filtered by filter 115. That is, each reference signal segment may be filtered by its corresponding filter coefficients.

A degraded signal may be filtered, creating filtered degraded signal segments (block 320). The degraded signal may be filtered by filter 115. That is, the entire degraded signal may be respectively filtered by the filter coefficients corresponding to each reference signal segment. As a result, filter 115 may output a number of filtered degraded signal segments that correspond to the number of filtered reference signal segments. Further, the frequency domain characteristics of the degraded signal may be modified in correspondence to the frequency domain characteristics associated with each reference signal segment. More particularly, an energy distribution within a frequency domain of the degraded signal may be modified in correspondence to an energy distribution within a frequency domain associated with each filtered reference signal segment.

Each filtered degraded signal segment may be time-aligned with each filtered reference signal segment (block 325). Aligner 120 may receive both the filtered reference signal segments and the filtered degraded signal segments. Aligner 120 may perform time-wise alignment for each filtered reference signal segment with respect to each corresponding filtered degraded signal segment. In one implementation, aligner 120 may determine a maximum cross-correlation between each filtered reference segment and corresponding filtered degraded signal pair. Aligner 120 may align the reference signal and the degraded signal based on the determined maximum cross-correlation associated with the filtered reference signal segment and the filtered degraded signal segment pair. In another implementation, aligner 120 may determine an error signal for each filtered reference signal segment and corresponding filtered degraded signal pair. Aligner 120 may select a minimum error signal from the determined error signals. Aligner 120 may align a segment of the reference signal with a corresponding segment of the degraded signal based on the selected minimum error signal or maximum correlation associated with the filtered reference signal segment and the filtered degraded signal segment pair.

A time offset may be output (block 330). Aligner 120 may output a time offset that corresponds to a time alignment between the segment of the reference signal and the corresponding segment of the degraded signal.

Although FIG. 3 illustrates an exemplary process 300, in other implementations, fewer, additional, and/or different operations may be performed.

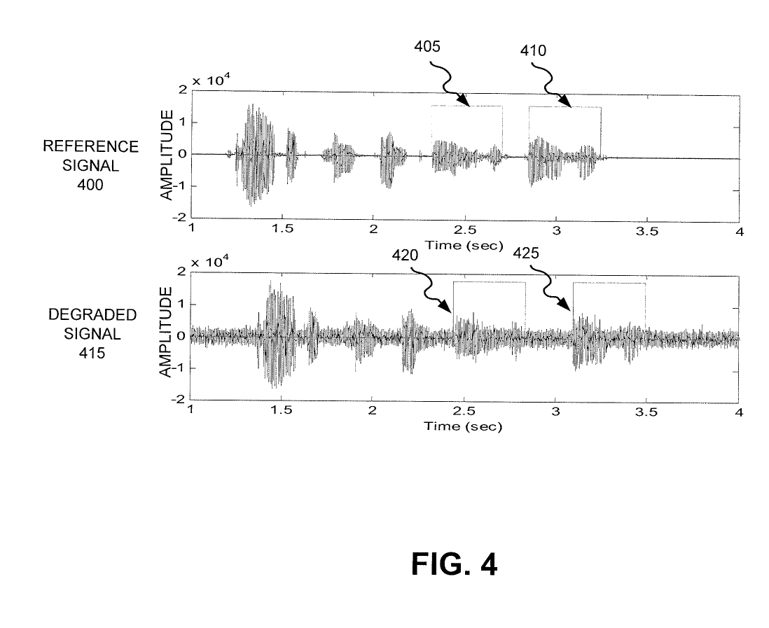

By way of example, FIGS. 4-6 are diagrams illustrating an example case in which the exemplary process 300 may be utilized. FIG. 4 is a diagram illustrating an exemplary reference signal 400 and an exemplary degraded signal 415. Reference signal 400 and degraded signal 415 may correspond to speech signals. For example, segments 405 and 410 of reference signal 400 correspond to segments 420 and 425 of degraded signal 415, where each of these segments 405, 410, 420, and 425 correspond to a spoken word. However, degraded signal 415 may include delay and noise. The degradation may stem from traversing one or more nodes of a communication network.

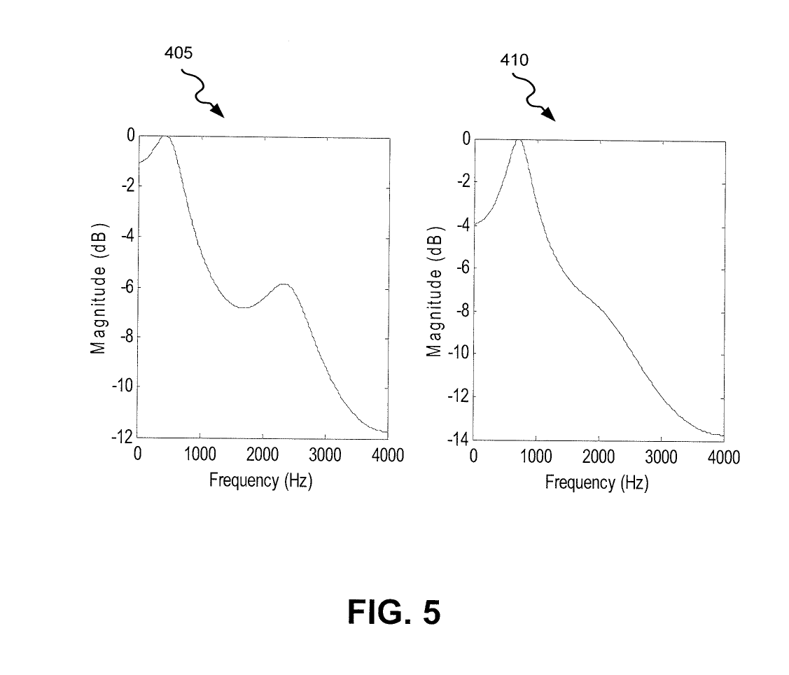

FIG. 5 is a diagram illustrating exemplary frequency responses for filtering segments associated with reference signal 400 and degraded signal 415. For example, filter coefficient calculator 110 may generate filtering coefficients for filter 415 corresponding to segments 405 and 410 of reference signal 400.

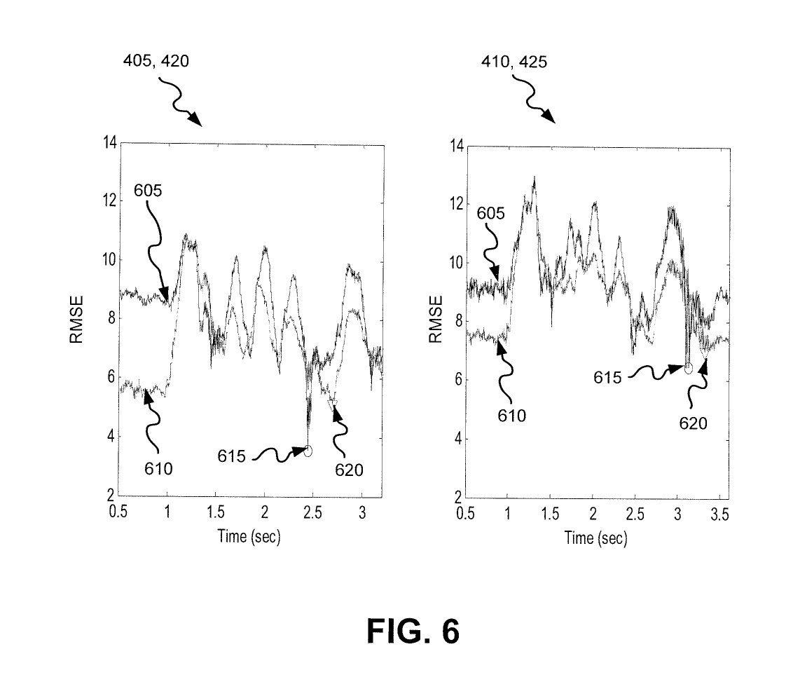

FIG. 6 is a diagram illustrating root mean square error (RMSE) signals associated with segments 405, 420, and 410, 425. As illustrated segments 605 represent RMSE signals when segments 405, 420 and 410, 425 have been filtered, respectively. Additionally, segments 610 represent RMSE signals when segments 405, 420 and 410, 425 have not been filtered. Points 615 and 620 represent minima of the RMSE signals. In one implementation, the RMSE signals may be calculated based on the energy of both segments (e.g., 405, 420), in the log domain, to yield signals E_{rL}(n) and E_{dL}(n), where n is the time window, r is the reference signal, and d is the degraded signal. A time domain method may be utilized, such as to minimize the RMSE D_{K} between E_{rL}(n) and E_{dL}(n+k), for all possible k, based on the following exemplary expression:

$$D ( k ) = {( \frac{1}{N} {\sum }_{n = 1}^{N} {( {E}_{rL} ( n ) - {E}_{dL} ( n + k ) )}^{2} )}^{1 / 2}$$

Referring back to FIG. 6, SAS 100 may calculate a time offset based on a time difference between points 615 and 620.

The foregoing description of implementations provides illustration, but is not intended to be exhaustive or to limit the implementations to the precise form disclosed. Modifications and variations are possible in light of the above teachings or may be acquired from practice of the teachings.

In addition, while a series of blocks has been described with regard to the process illustrated in FIG. 3, the order of the blocks may be modified in other implementations. Further, non-dependent blocks may be performed in parallel. It will be appreciated that the process and/or operations described herein may be implemented as a computer program. The computer program may be stored on a computer-readable medium (e.g., a memory, a hard disk, a CD, a DVD, etc.) or represented in some other type of medium (e.g., a transmission medium).

It will be apparent that aspects described herein may be implemented in many different forms of software, firmware, and hardware in the implementations illustrated in the figures. The actual software code or specialized control hardware used to implement aspects does not limit the invention. Thus, the operation and behavior of the aspects were described without reference to the specific software code—it being understood that software and control hardware can be designed to implement the aspects based on the description herein.

Even though particular combinations of features are recited in the claims and/or disclosed in the specification, these combinations are not intended to limit the disclosure of the invention. In fact, many of these features may be combined in ways not specifically recited in the claims and/or disclosed in the specification.

It should be emphasized that the term “comprises” or “comprising” when used in the specification is taken to specify the presence of stated features, integers, steps, or components but does not preclude the presence or addition of one or more other features, integers, steps, components, or groups thereof.

No element, act, or instruction used in the present application should be construed as critical or essential to the implementations described herein unless explicitly described as such.

The term “may” is used throughout this application and is intended to be interpreted, for example, as “having the potential to,” configured to,” or “capable of,” and not in a mandatory sense (e.g., as “must”). The terms “a” and “an” are intended to be interpreted to include, for example, one or more items. Where only one item is intended, the term “one” or similar language is used. Further, the phrase “based on” is intended to be interpreted to mean, for example, “based, at least in part, on,” unless explicitly stated otherwise. The term “and/or” is intended to be interpreted to include any and all combinations of one or more of the associated list items.

1-21. (canceled)

22. A method performed by a device for aligning signals having a time delay difference, comprising:
segmenting a reference signal into a plurality of reference signal segments, wherein the reference signal is a non-degraded signal;
generating filter coefficients based on each reference signal segment;
filtering each reference signal segment with its corresponding generated filter coefficients;
filtering a degraded signal, which comprises a delayed form of the reference signal, with each of the generated filtering coefficients to produce a number of degraded signals equivalent to a number of the reference signal segments;
performing time-wise alignment for each filtered degraded signal with respect to each corresponding filtered reference signal segment; and
outputting a time offset based on that time-wise alignment.

23. The method of claim 22, where the generating comprises generating an auto-regressive model for each reference signal segment.

24. The method of claim 22, where the reference signal includes an audio signal, and the delayed signal includes at least one of a piecewise delay of the reference signal or a continuous delay of the reference signal.

25. The method of claim 22, where the filtering of the degraded signal comprises modifying frequency domain characteristics of the degraded signal in correspondence to frequency domain characteristics associated with each reference signal segment.

26. The method of claim 25, where the modifying the frequency domain characteristics of the degraded signal comprises modifying an energy distribution within a frequency domain of the degraded signal in correspondence to an energy distribution within a frequency domain associated with each filtered reference signal segment.

27. The method of claim 22, where the performing time-wise alignment comprises:
determining a maximum of correlation between each filtered reference signal segment and corresponding filtered degraded signal pair, or
determining an error signal for each filtered reference signal segment and corresponding filtered degraded signal pair; and selecting a minimum error signal from error signals associated with the respective filtered reference signal segments and corresponding filtered processing signal pairs.

28. The method of claim 27, further comprising performing time-wise alignment based on the selected minimum error signal.

29. The method of claim 22, where the device includes a computer.

30. A device for aligning signals having a time delay difference, comprising a signal alignment system configured to:
segment a reference signal into a plurality of reference signal segments, wherein the reference signal is a non-degraded signal;
generate filter coefficients based on each reference signal segment;
filter each reference signal segment with its corresponding generated filter coefficients;
filter a degraded signal, which comprises a delayed form of the reference signal, with each of the generated filtering coefficients to produce a number of degraded signals equivalent to a number of the reference signal segments;
perform time-wise alignment for each filtered degraded signal with respect to each corresponding filtered reference signal segment; and
output, based on that time-wise alignment, a time offset corresponding to a time delay difference between the reference signal and the degraded signal.

31. The device of claim 30, wherein the signal alignment system is configured to generate the filtering coefficients based on a parametric method or a non-parametric method.

32. The device of claim 30, where the reference signal and the degraded signal are both a speech signal.

33. The device of claim 30, wherein the time alignment system is configured to modify frequency domain characteristics of the degraded signal based on frequency domain characteristics associated with each filtered reference signal segment.

34. The device of claim 30, wherein the device is configured to receive the degraded signal from a node in a communication network.

35. The device of claim 30, wherein the signal alignment system is configured to perform time-wise alignment by:
determining an error signal for each filtered reference signal segment and filtered degraded signal pair, and
selecting a minimum error signal.

36. The device of claim 35, wherein the signal alignment system is further configured to perform time-wise alignment based on the selected minimum error signal.

37. The device of claim 30, wherein the signal alignment system is configured to determine a maximum correlation between each filtered reference signal segment and filtered degraded signal pair, and perform time-wise alignment based on the determined maximum correlation.

38. A computer program product stored on a computer-readable medium and comprising computer program instructions that, when executed by a processor of a device, cause the device to align signals having a time delay difference, the instructions causing the device to:
segment a reference signal into a plurality of reference signal segments, wherein the reference signal is a non-degraded signal;
generate filter coefficients based on each reference signal segment;
filter each reference signal segment with its corresponding generated filter coefficients;
filter a degraded signal, which comprises a delayed form of the reference signal, with each of the generated filtering coefficients to produce a number of degraded signals equivalent to a number of the plurality of reference signal segments;
perform time-wise alignment for each filtered degraded signal with respect to each corresponding filtered reference signal segment; and
output a time offset based on that time-wise alignment.

39. The computer program product of claim 38, wherein one or more instructions that cause the device to perform time-wise alignment include one or more instructions that cause the device to:
determine an error signal for each filtered reference signal segment and filtered degraded signal pair;
select a minimum error signal; and
perform time-wise alignment based on the selected minimum error signal.

40. The computer program product of claim 39, wherein one or more instructions that cause the device to perform time-wise alignment based on the selected minimum error signal include one or more instructions that cause the device to determine the time offset between one of the filtered reference signal segment and filtered degraded signal pairs that is associated with the selected minimum error signal.

41. The computer program product of claim 38, wherein one or more instructions that cause the device to perform time-wise alignment include one or more instructions that cause the device to determine a maximum correlation between each filtered reference signal segment and filtered degraded signal pair.
